(19) United States
(12) Patent Application Publication
(10) Pub. No.: US 2023/0399511 A1
(43) Pub. Date: Dec. 14, 2023

(54) RESIN COMPOSITION, PREPREG, RESIN-COATED FILM, RESIN-COATED METAL FOIL, METAL-CLAD LAMINATE, AND WIRING BOARD

(71) Applicant: PANASONIC INTELLECTUAL PROPERTY MANAGEMENT CO., LTD., Osaka (JP)

(72) Inventors: Hiroaki UMEHARA, Fukushima (JP); Hirosuke SAITO, Osaka (JP)

(73) Assignee: PANASONIC INTELLECTUAL PROPERTY MANAGEMENT CO., LTD., Osaka (JP)

(21) Appl. No.: 18/025,158

(22) PCT Filed: Sep. 9, 2021
(86) PCT No.: PCT/JP2021/033117

§ 371 Date: Mar. 7, 2023

(30) Foreign Application Priority Data
Sep. 11, 2020 (JP) 2020-153177

(51) Int. Cl. C08L 71/12; C08J 5/24; H05K 1/03

(52) U.S. Cl. CPC C08L 71/123; C08J 5/244; H05K 2201/0209; C08J 2371/12; C08J 2425/06; H05K 1/0373

(57) ABSTRACT

A resin composition contains a polyphenylene ether compound having a carbon-carbon unsaturated double bond at the terminal, a maleimide compound (A) having an arylene structure bonded in the meta-orientation in the molecule, and an inorganic filler.

### TECHNICAL FIELD

The present invention relates to a resin composition, a prepreg, a film with resin, a metal foil with resin, a metal-clad laminate, and a wiring board.

### BACKGROUND ART

As the information processing quantity by various kinds of electronic equipment increases, mounting technologies such as high integration of semiconductor devices to be mounted, densification of wiring, and multilayering are progressing. In addition, wiring boards used in various kinds of electronic equipment are required to be, for example, high-frequency compatible wiring boards such as a millimeter-wave radar board for in-vehicle use. Substrate materials for forming insulating layers of wiring boards used in various kinds of electronic equipment are required to have a low relative dielectric constant and a low dielectric loss tangent in order to increase the signal transmission speed and to decrease the signal transmission loss.

It is known that polyphenylene ether exhibits excellent low dielectric properties such as a low relative dielectric constant and a low dielectric loss tangent and exhibits excellent low dielectric properties such as a low relative dielectric constant and a low dielectric loss tangent in a high frequency band (high frequency region) from the MHz band to the GHz band as well. For this reason, it has been investigated that polyphenylene ether is used, for example, as a high frequency molding material. More specifically, polyphenylene ether is preferably used as a substrate material for forming an insulating layer of a wiring board to be equipped in electronic equipment utilizing a high frequency band.

Substrate materials for forming insulating layers of wiring boards are also required not only to exhibit excellent low dielectric properties but also to exhibit enhanced curability so as to afford a cured product exhibiting excellent heat resistance and the like. Hence, it is conceivable that the heat resistance is enhanced by using a polyphenylene ether compound having a carbon-carbon unsaturated double bond at the terminal as a substrate material. As a resin composition containing such a polyphenylene ether compound having a carbon-carbon unsaturated double bond at the terminal, for example, the resin composition described in Patent Literature 1 may be mentioned.

Patent Literature 1 describes a resin composition containing a polymaleimide compound having a predetermined structure such as one having a 4,4′-biphenyl group in the molecule, modified polyphenylene ether of which the terminal is modified with a substituent containing a carbon-carbon unsaturated double bond, and a filler. According to Patent Literature 1, it is disclosed that it is possible to provide a resin composition that can simultaneously satisfy excellent peel strength, low water absorbing properties, desmear resistance, and heat resistance when used as a material for printed wiring board, or the like.

Metal-clad laminates and metal foils with resin used in the manufacture of wiring boards and the like include not only an insulating layer but also a metal foil on the insulating layer. Wiring boards also include not only an insulating layer but also wiring on the insulating layer. Examples of the wiring include wiring derived from a metal foil equipped in the metal-clad laminate or the like.

In recent years, particularly small portable devices such as mobile communication terminals and notebook PCs have been rapidly becoming multi-functional, high performance, slim and compact. Along with this, in wiring boards used in these products as well, there is a further demand for miniaturization of conductor wiring, multilayering of conductor wiring layers, thinning, and improvement in performance such as mechanical properties. In particular, as thinning and multilayering of wiring boards progresses, problems arise that semiconductor packages in which semiconductor chips are mounted on wiring boards are warped and mounting failures and conduction failures are likely to occur. In order to suppress mounting failures and conduction failures of semiconductor packages in which semiconductor chips are mounted on wiring boards, the insulating layers are required to have low coefficients of thermal expansion. Hence, substrate materials for forming insulating layers of wiring boards are required to afford cured products having low coefficients of thermal expansion.

In the wiring boards, miniaturized wiring is also required not to peel off from the insulating layers and thus it is further required that adhesive properties between the wiring and the insulating layers are high. Hence, it is required that adhesive properties between the metal foils and the insulating layers are high in metal-clad laminates and metal foils with resin, and substrate materials for forming insulating layers of wiring boards are required to afford cured products exhibiting excellent adhesive properties to metal foils.

Since wiring boards used in various kinds of electronic equipment may be exposed to high temperature environments for reflow during board processing such as mounting of semiconductor chips, substrate materials for forming wiring boards are required to exhibit high heat resistance such as a high glass transition temperature.

Furthermore, in order to suppress loss due to increased resistance accompanying miniaturization of wiring, the insulating layers equipped in wiring boards are further required to have a low relative dielectric constant and a low dielectric loss tangent.

### CITATION LIST

### Patent Literature

Patent Literature 1: WO 2019/138992 A

### SUMMARY OF INVENTION

The present invention has been made in view of such circumstances, and an object thereof is to provide a resin composition, which affords a cured product exhibiting excellent low dielectric properties, heat resistance, and adhesive properties to a metal foil and a low coefficient of thermal expansion. Another object of the present invention is to provide a prepreg, a film with resin, a metal foil with resin, a metal-clad laminate, and a wiring board, which are obtained using the resin composition.

An aspect of the present invention is a resin composition containing a polyphenylene ether compound having a carbon-carbon unsaturated double bond at the terminal, a maleimide compound (A) having an arylene structure bonded in the meta-orientation in the molecule, and an inorganic filler.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

The present inventors have found out that the objects are achieved by the present invention described below as a result of extensive studies.

Hereinafter, embodiments according to the present invention will be described, but the present invention is not limited thereto.

### Resin Composition

The resin composition according to the present embodiment is a resin composition containing a polyphenylene ether compound having a carbon-carbon unsaturated double bond at the terminal, a maleimide compound (A) having an arylene structure bonded in the meta-orientation in the molecule, and an inorganic filler. By curing the resin composition having such a configuration, a cured product is obtained which exhibits excellent low dielectric properties, heat resistance, and adhesive properties to a metal foil and a low coefficient of thermal expansion.

First, as the resin composition contains the inorganic filler, the coefficient of theimal expansion can be decreased. It is considered that the resin composition can be suitably cured by curing the polyphenylene ether compound together with the maleimide compound (A) although the resin composition contains the inorganic filler, and a cured product is obtained which exhibits high heat resistance while maintaining the excellent low dielectric properties of polyphenylene ether. It is considered that it is possible to enhance the adhesive properties of the cured product obtained to a metal foil by curing the polyphenylene ether compound together with the maleimide compound (A). Since the resin composition can be suitably cured, it is considered that the coefficient of thermal expansion of the cured product obtained can be decreased. From these facts, it is considered that the resin composition affords a cured product, which exhibits excellent low dielectric properties, heat resistance, and adhesive properties to a metal foil and a low coefficient of thermal expansion.

### Polyphenylene Ether Compound

The polyphenylene ether compound is not particularly limited as long as it is a polyphenylene ether compound having a carbon-carbon unsaturated double bond at the terminal. Examples of the polyphenylene ether compound include a polyphenylene ether compound having a carbon-carbon unsaturated double bond at the molecular terminal, and more specific examples thereof include a polyphenylene ether compound having a substituent having a carbon-carbon unsaturated double bond at the molecular terminal such as a modified polyphenylene ether compound of which the terminal is modified with a substituent having a carbon-carbon unsaturated double bond.

Examples of the substituent having a carbon-carbon unsaturated double bond include a group represented by the following Formula (3) and a group represented by the following Formula (4). In other words, examples of the polyphenylene ether compound include a polyphenylene ether compound having at least one selected from a group represented by the following Formula (3) and a group represented by the following Formula (4) at the molecular terminal.

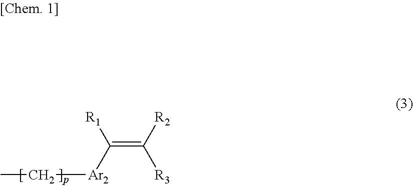

In Formula (3), R₁ to R₃ are independent of each other. In other words, R₁ to R₃ may be the same group as or different groups from each other. R₁ to R₃ represent a hydrogen atom or an alkyl group. Ar₂ represents an arylene group. p represents 0 to 10. In a case where p in Formula (3) is 0, it indicates that Ar₂ is directly bonded to the terminal of polyphenylene ether.

The arylene group is not particularly limited. Examples of this arylene group include a monocyclic aromatic group such as a phenylene group and a polycyclic aromatic group that is polycyclic aromatic such as a naphthalene ring. This arylene group also includes a derivative in which a hydrogen atom bonded to an aromatic ring is substituted with a functional group such as an alkenyl group, an alkynyl group, a formyl group, an alkylcarbonyl group, an alkenylcarbonyl group, or an alkynylcarbonyl group.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

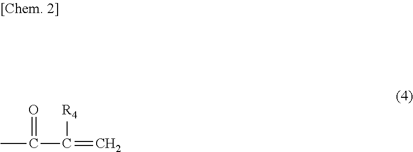

In Formula (4), R₄ represents a hydrogen atom or an alkyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

Examples of the group represented by Formula (3) include a vinylbenzyl group (ethenylbenzyl group) represented by the following Formula (5). Examples of the group represented by Formula (4) include an acryloyl group and a methacryloyl group.

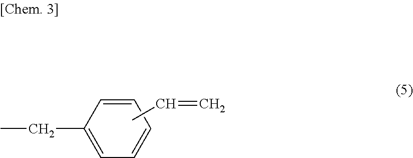

More specific examples of the substituent include vinylbenzyl groups (ethenylbenzyl groups) such as an o-ethenylbenzyl group, a m-ethenylbenzyl group, and a p-ethenylbenzyl group, a vinylphenyl group, an acryloyl group, and a methacryloyl group. The polyphenylene ether compound may have one kind of substituent or two or more kinds of substituents as the substituent. The polyphenylene ether compound may have, for example, any of an o-ethenylbenzyl group, a m-ethenylbenzyl group, or a p-ethenylbenzyl group, or two or three kinds thereof.

The polyphenylene ether compound has a polyphenylene ether chain in the molecule and preferably has, for example, a repeating unit represented by the following Formula (6) in the molecule.

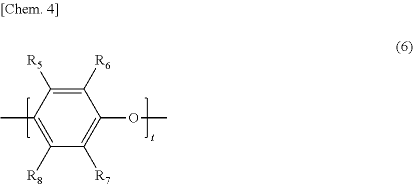

In Formula (6), t represents 1 to 50. R₅ to R₈ are independent of each other. In other words, R₅ to R₈ may be the same group as or different groups from each other. R₅ to R₈ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

Specific examples of the respective functional groups mentioned in R₅ to R₈ include the following.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms and more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms and more preferably an alkynyl group having 2 to 10 carbon atoms. Specific examples thereof include an ethynyl group and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms and more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms and more preferably an alkenylcarbonyl group having 3 to 10 carbon atoms. Specific examples thereof include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms and more preferably an alkynylcarbonyl group having 3 to 10 carbon atoms. Specific examples thereof include a propioloyl group.

The weight average molecular weight (Mw) and number average molecular weight (Mn) of the polyphenylene ether compound are not particularly limited, and specifically, are preferably 500 to 5,000, more preferably 800 to 4,000, still more preferably 1,000 to 3,000. Here, the weight average molecular weight and number average molecular weight may be those measured by general molecular weight measurement methods, and specific examples thereof include values measured by gel permeation chromatography (GPC). In a case where the polyphenylene ether compound has a repeating unit represented by Formula (6) in the molecule, t is preferably a numerical value so that the weight average molecular weight and number average molecular weight of the polyphenylene ether compound is in such a range. Specifically, t is preferably 1 to 50.

When the weight average molecular weight and number average molecular weight of the polyphenylene ether compound are in the above range, the excellent low dielectric properties of polyphenylene ether are exhibited, and not only the heat resistance of the cured product is superior but also the moldability is excellent. This is considered to be due to the following. When the weight average molecular weight and number average molecular weight of ordinary polyphenylene ether are in the above range, the molecular weight is relatively low, and thus the heat resistance tends to decrease. With regard to this point, it is considered that since the polyphenylene ether compound according to the present embodiment has one or more unsaturated double bonds at the terminal, a cured product exhibiting sufficiently high heat resistance is obtained as the curing reaction proceeds. When the weight average molecular weight and number average molecular weight of the polyphenylene ether compound are in the above range, it is considered that the molecular weight is relatively low and thus the moldability is also excellent. Hence, it is considered that such a polyphenylene ether compound not only imparts superior heat resistance to the cured product but also exhibits excellent moldability.

In the polyphenylene ether compound, the average number of the substituents (number of terminal functional groups) at the molecule terminal per one molecule of the polyphenylene ether compound is not particularly limited. Specifically, the average number is preferably 1 to 5, more preferably 1 to 3, and still more preferably 1.5 to 3. When the number of terminal functional groups is too small, sufficient heat resistance of the cured product tends to be hardly attained. When the number of terminal functional groups is too large, the reactivity is too high and, for example, troubles such as deterioration in the storage stability of the resin composition or deterioration in the fluidity of the resin composition may occur. In other words, when such a polyphenylene ether compound is used, for example, molding defects such as generation of voids at the time of multilayer molding occur by insufficient fluidity and the like and a problem of moldability that a highly reliable printed wiring board is hardly obtained may occur.

The number of terminal functional groups in the polyphenylene ether compound includes a numerical value expressing the average value of the substituents per one molecule of all the polyphenylene ether compounds present in 1 mole of the polyphenylene ether compound. This number of terminal functional groups can be determined by, for example, measuring the number of hydroxyl groups remaining in the obtained polyphenylene ether compound and calculating the number of hydroxyl groups decreased from the number of hydroxyl groups in the polyphenylene ether before having (before being modified with) the substituent. The number of hydroxyl groups decreased from the number of hydroxyl groups in the polyphenylene ether before being modified is the number of terminal functional groups. Moreover, with regard to the method for measuring the number of hydroxyl groups remaining in the polyphenylene ether compound, the number of hydroxyl groups can be determined by adding a quaternary ammonium salt (tetraethylammonium hydroxide) to be associated with a hydroxyl group to a solution of the polyphenylene ether compound and measuring the UV absorbance of the mixed solution.

The intrinsic viscosity of the polyphenylene ether compound is not particularly limited. Specifically, the intrinsic viscosity may be 0.03 to 0.12 dl/g, and is preferably 0.04 to 0.11 dl/g and more preferably 0.06 to 0.095 dl/g. When this intrinsic viscosity is too low, the molecular weight tends to be low and low dielectric properties such as a low relative dielectric constant and a low dielectric loss tangent tend to be hardly attained. When the intrinsic viscosity is too high, the viscosity is high, sufficient fluidity is not attained, and the moldability of the cured product tends to decrease. Hence, when the intrinsic viscosity of the polyphenylene ether compound is in the above range, excellent heat resistance and moldability of the cured product can be realized.

Note that the intrinsic viscosity here is an intrinsic viscosity measured in methylene chloride at 25° C. and more specifically is, for example, a value attained by measuring the intrinsic viscosity of a methylene chloride solution (liquid temperature: 25° C.) at 0.18 g/45 ml using a viscometer. Examples of the viscometer include AVS500 Visco System manufactured by SCHOTT Instruments GmbH.

Examples of the polyphenylene ether compound include a polyphenylene ether compound represented by the following Formula (7) and a polyphenylene ether compound represented by the following Formula (8). As the polyphenylene ether compound, these polyphenylene ether compounds may be used singly or these two kinds of polyphenylene ether compounds may be used in combination.

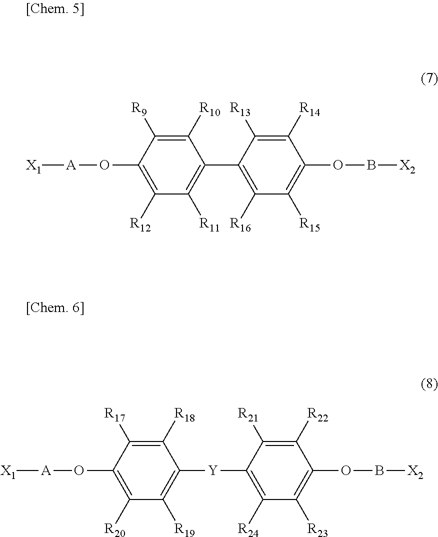

In Formulas (7) and (8), R₉ to R₁₆ and R₁₇ to R₂₄ are independent of each other. In other words, R₉ to R₁₆ and R₁₇ to R₂₄ may be the same group as or different groups from each other. R₉ to R₁₆ and R₁₇ to R₂₄ represent a hydrogen atom, an alkyl group, an alkenyl group, an alkynyl group, a formyl group, an alkylcarbonyl group, an alkenylcarbonyl group, or an alkynylcarbonyl group. X₁ and X₂ are independent of each other. In other words, X₁ and X 2 may be the same group as or different groups from each other. X₁ and X₂ represent a substituent having a carbon-carbon unsaturated double bond. A and B represent a repeating unit represented by the following Formula (9) and a repeating unit represented by the following Formula (10), respectively. In Formula (8), Y represents a linear, branched, or cyclic hydrocarbon having 20 or less carbon atoms.

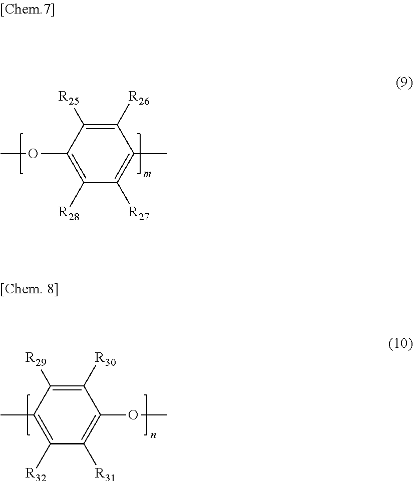

In Formulas (9) and (10), m and n each represent 0 to 20. R₂₅ to R₂₈ and R₂₉ to R₃₂ are independent of each other. In other words, R₂₅ to R₂₈ and R₂₉ to R₃₂ may be the same group as or different groups from each other. R₂₅ to R₂₈ and R₂₉ to R₃₂ represent a hydrogen atom, an alkyl group, an alkenyl group, an alkynyl group, a formyl group, an alkylcarbonyl group, an alkenylcarbonyl group, or an alkynylcarbonyl group.

The polyphenylene ether compound represented by Formula (7) and the polyphenylene ether compound represented by Formula (8) are not particularly limited as long as they are compounds satisfying the configuration. Specifically, in Formulas (7) and (8), R₉ to R₁₆ and R₁₇ to R₂₄ are independent of each other as described above. In other words, R₉ to R₁₆ and R₁₇ to R₂₄ may be the same group as or different groups from each other. R₉ to R₁₆ and R₁₇ to R₂₄ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

In Formulas (9) and (10), m and n each preferably represent 0 to 20 as described above. In addition, it is preferable that m and n represent numerical values so that the sum of m and n is 1 to 30. Hence, it is more preferable that m represents 0 to 20, n represents 0 to 20, and the sum of m and n represents 1 to 30. R₂₅ to R₂₈ and R₂₉ to R₃₂ are independent of each other. In other words, R₂₅ to R₂₈ and R₂₉ to R₃₂ may be the same group as or different groups from each other. R₂₅ to R₂₈ and R₂₉ to R₃₂ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

R₉ to R₃₂ are the same as R₅ to R₈ in Formula (6).

In Formula (8), Y represents a linear, branched, or cyclic hydrocarbon having 20 or less carbon atoms as described above. Examples of Y include a group represented by the following Formula (11).

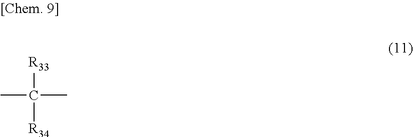

In Formula (11), R₃₃ and R₃₄ each independently represent a hydrogen atom or an alkyl group. Examples of the alkyl group include a methyl group. Examples of the group represented by Formula (11) include a methylene group, a methylmethylene group, and a dimethylmethylene group. Among these, a dimethylmethylene group is preferable.

In Formulas (7) and (8), X₁ and X₂ each independently represent a substituent having a carbon-carbon double bond. In the polyphenylene ether compound represented by Formula (7) and the polyphenylene ether compound represented by Formula (8), X₁ and X₂ may be the same group as or different groups from each other.

More specific examples of the polyphenylene ether compound represented by Formula (7) include a polyphenylene ether compound represented by the following Formula (12).

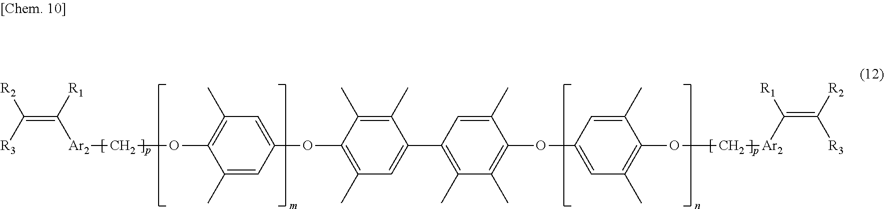

More specific examples of the polyphenylene ether compound represented by Formula (8) include a polyphenylene ether compound represented by the following Formula (13) and a polyphenylene ether compound represented by the following Formula (14).

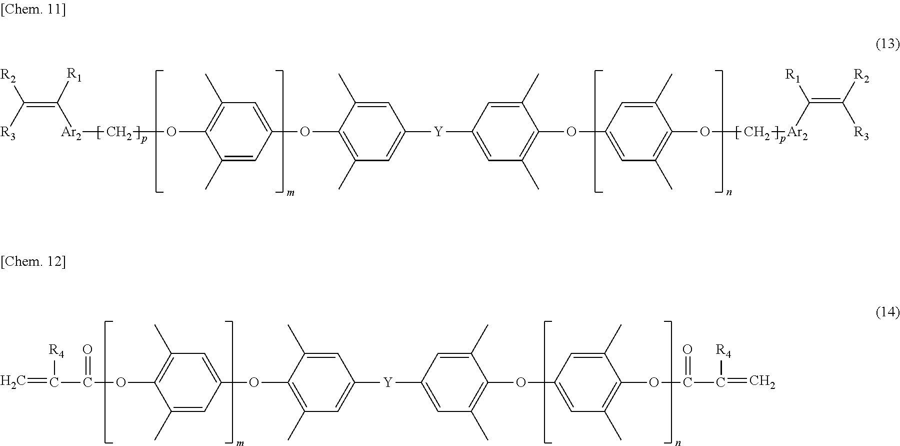

In Formulas (12) to (14), m and n are the same as m and n in Formulas (9) and (10). In Formulas (12) and (13), R₁ to R₃, p, and Ar₂ are the same as R₁ to R₃, p, and Ar₂ in Formula (3). In Formulas (13) and (14), Y is the same as Y in Formula (8). In Formula (14), R₄ is the same as R₄ in Formula (4).

The method for synthesizing the polyphenylene ether compound used in the present embodiment is not particularly limited as long as a polyphenylene ether compound having a carbon-carbon unsaturated double bond in the molecule can be synthesized. Specific examples of this method include a method in which polyphenylene ether is reacted with a compound in which a substituent having a carbon-carbon unsaturated double bond is bonded to a halogen atom.

Examples of the compound in which a substituent having a carbon-carbon unsaturated double bond is bonded to a halogen atom include compounds in which substituents represented by Formulas (3) to (5) are bonded to a halogen atom. Specific examples of the halogen atom include a chlorine atom, a bromine atom, an iodine atom, and a fluorine atom. Among these, a chlorine atom is preferable. More specific examples of the compound in which a substituent having a carbon-carbon unsaturated double bond is bonded to a halogen atom include o-chloromethylstyrene, p-chloromethylstyrene, and m-chloromethylstyrene. The compound in which a substituent having a carbon-carbon unsaturated double bond is bonded to a halogen atom may be used singly or in combination of two or more kinds thereof. For example, o-chloromethylstyrene, p-chloromethylstyrene, and m-chloromethylstyrene may be used singly or in combination of two or three kinds thereof.

Polyphenylene ether that is a raw material is not particularly limited as long as a predetermined polyphenylene ether compound can be finally synthesized. Specific examples thereof include those containing polyphenylene ether containing 2,6-dimethylphenol and at least one of a bifunctional phenol and a trifunctional phenol and polyphenylene ether such as poly(2,6-dimethyl-1,4-phenylene oxide) as a main component. The bifunctional phenol is a phenol compound having two phenolic hydroxyl groups in the molecule, and examples thereof include tetramethyl bisphenol A. The trifunctional phenol is a phenol compound having three phenolic hydroxyl groups in the molecule.

Examples of the method for synthesizing the polyphenylene ether compound include the methods described above. Specifically, polyphenylene ether as described above and the compound in which a substituent having a carbon-carbon unsaturated double bond is bonded to a halogen atom are dissolved in a solvent and stirred. By doing so, polyphenylene ether reacts with the compound in which a substituent having a carbon-carbon unsaturated double bond is bonded to a halogen atom, and the polyphenylene ether compound used in the present embodiment is obtained.

The reaction is preferably conducted in the presence of an alkali metal hydroxide. By doing so, it is considered that this reaction suitably proceeds. This is considered to be because the alkali metal hydroxide functions as a dehydrohalogenating agent, specifically, a dehydrochlorinating agent. In other words, it is considered that the alkali metal hydroxide eliminates the hydrogen halide from the phenol group in polyphenylene ether and the compound in which a substituent having a carbon-carbon unsaturated double bond is bonded to a halogen atom, and by doing so, the substituent having a carbon-carbon unsaturated double bond is bonded to the oxygen atom of the phenol group instead of the hydrogen atom of the phenol group in polyphenylene ether.

The alkali metal hydroxide is not particularly limited as long as it can act as a dehalogenating agent, and examples thereof include sodium hydroxide. In addition, the alkali metal hydroxide is usually used in the form of an aqueous solution and is specifically used as an aqueous sodium hydroxide solution.

The reaction conditions such as reaction time and reaction temperature also vary depending on the compound in which a substituent having a carbon-carbon unsaturated double bond is bonded to a halogen atom, and the like, and are not particularly limited as long as they are conditions under which the reaction as described above suitably proceeds. Specifically, the reaction temperature is preferably room temperature to 100° C. and more preferably 30° C. to 100° C. In addition, the reaction time is preferably 0.5 to 20 hours and more preferably 0.5 to 10 hours.

The solvent used at the time of the reaction is not particularly limited as long as it can dissolve polyphenylene ether and the compound in which a substituent having a carbon-carbon unsaturated double bond is bonded to a halogen atom, and does not inhibit the reaction of polyphenylene ether with the compound in which a substituent having a carbon-carbon unsaturated double bond is bonded to a halogen atom. Specific examples thereof include toluene.

The above reaction is preferably conducted in the presence of not only an alkali metal hydroxide but also a phase transfer catalyst. In other words, the above reaction is preferably conducted in the presence of an alkali metal hydroxide and a phase transfer catalyst. By doing so, it is considered that the above reaction more suitably proceeds. This is considered to be due to the following. This is considered to be because the phase transfer catalyst is a catalyst which has a function of taking in the alkali metal hydroxide, is soluble in both phases of a phase of a polar solvent such as water and a phase of a non-polar solvent such as an organic solvent, and can transfer between these phases. Specifically, in a case where an aqueous sodium hydroxide solution is used as an alkali metal hydroxide and an organic solvent, such as toluene, which is incompatible with water is used as a solvent, it is considered that when the aqueous sodium hydroxide solution is dropped into the solvent subjected to the reaction as well, the solvent and the aqueous sodium hydroxide solution are separated from each other and the sodium hydroxide is hardly transferred to the solvent. In that case, it is considered that the aqueous sodium hydroxide solution added as an alkali metal hydroxide hardly contributes to the promotion of the reaction. In contrast, when the reaction is conducted in the presence of an alkali metal hydroxide and a phase transfer catalyst, it is considered that the alkali metal hydroxide is transferred to the solvent in the state of being taken in the phase transfer catalyst and the aqueous sodium hydroxide solution is likely to contribute to the promotion of the reaction. For this reason, when the reaction is conducted in the presence of an alkali metal hydroxide and a phase transfer catalyst, it is considered that the above reaction more suitably proceeds.

The phase transfer catalyst is not particularly limited, and examples thereof include quaternary ammonium salts such as tetra-n-butylammonium bromide.

The resin composition used in the present embodiment preferably contains a polyphenylene ether compound obtained as described above as the polyphenylene ether compound.

### Maleimide Compound (A)

The maleimide compound (A) is not particularly limited as long as it is a maleimide compound having an arylene structure bonded in the meta-orientation in the molecule. Examples of the arylene structure bonded in the meta-orientation include an arylene structure in which a structure containing a maleimide group is bonded at the meta position (an arylene structure in which a structure containing a maleimide group is substituted at the meta position). The arylene structure bonded in the meta-orientation is an arylene group bonded in the meta-orientation, such as a group represented by the following Formula (15). Examples of the arylene structure bonded in the meta-orientation include m-arylene groups such as a m-phenylene group and a m-naphthylene group, and more specific examples thereof include a group represented by the following Formula (15).

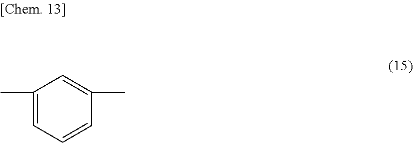

Examples of the maleimide compound (A) include a maleimide compound (A1) represented by the following Formula (1), and more specific examples thereof include a maleimide compound (A2) represented by the following Formula (2).

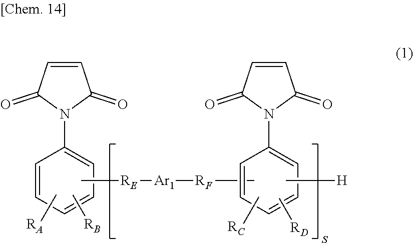

In Formula (1), Ar₁ represents an arylene group bonded in the meta-orientation. R_{A}, R_{B}, R_{C}, and R_{D} are independent of each other. In other words, R_{A}, R_{B}, R_{C}, and R_{D} may be the same group as or different groups from each other. R_{A}, R_{B}, R_{C}, and R_{D} represent a hydrogen atom, an alkyl group having 1 to 5 carbon atoms, or a phenyl group, preferably a hydrogen atom. R_{E} and R_{F} are independent of each other. In other words, R_{E} and R_{F} may be the same group as or different groups from each other. R_{E} and R_{F} represent an aliphatic hydrocarbon group. s represents 1 to 5.

The arylene group is not particularly limited as long as it is an arylene group bonded in the meta-orientation, examples thereof include m-arylene groups such as a m-phenylene group and a m-naphthylene group, and more specific examples thereof include a group represented by Formula (15).

Examples of the alkyl group having 1 to 5 carbon atoms include a methyl group, an ethyl group, a propyl group, an isopropyl group, a n-butyl group, a sec-butyl group, an isobutyl group, a tert-butyl group, a pentyl group, and a neopentyl group.

The aliphatic hydrocarbon group is a divalent group and may be acyclic or cyclic. Examples of the aliphatic hydrocarbon group include an alkylene group, and more specific examples thereof include a methylene group, a methylmethylene group, and a dimethylmethylene group. Among these, a dimethylmethylene group is preferable.

In the maleimide compound (A1) represented by Formula (1), s, which is the number of repetitions, is preferably 1 to 5. This s is the average value of the number of repetitions (degree of polymerization).

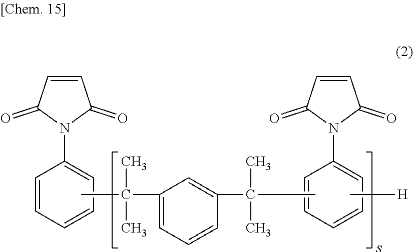

In Formula (2), s represents 1 to 5. This s is the same as s in Formula (1) and is the average value of the number of repetitions (degree of polymerization).

As long as s, which is the average value of the number of repetitions (degree of polymerization), is 1 to 5, the maleimide compound (A1) represented by Formula (1) and the maleimide compound (A2) represented by Formula (2) may include a monofunctional form in which s is 0 or a polyfunctional form such as a heptafunctional form or an octafunctional form in which s is 6 or more.

As the maleimide compound (A), a commercially available product can be used, and for example, the solid component in MIR-5000-60T manufactured by Nippon Kayaku Co., Ltd. may be used.

As the maleimide compound (A), the maleimide compounds exemplified above may be used singly or in combination of two or more kinds thereof. As the maleimide compound (A), the maleimide compound (A1) represented by Formula (1) may be used singly or the maleimide compound (A1) represented by Formula (1) may be used in combination of two or more kinds thereof. Examples of the combined use of two or more kinds of the maleimide compound (A1) represented by Formula (1) include concurrent use of the maleimide compound (A1) represented by Formula (1) other than the maleimide compound (A2) represented by Formula (2) with the maleimide compound (A2) represented by Formula (2).

### Inorganic Filler

The inorganic filler is not particularly limited as long as it is an inorganic filler that can be used as an inorganic filler contained in a resin composition. Examples of the inorganic filler include metal oxides such as silica, alumina, titanium oxide, magnesium oxide and mica, metal hydroxides such as magnesium hydroxide and aluminum hydroxide, talc, aluminum borate, barium sulfate, aluminum nitride, boron nitride, barium titanate, magnesium carbonate such as anhydrous magnesium carbonate, and calcium carbonate. Among these, silica, metal hydroxides such as magnesium hydroxide and aluminum hydroxide, aluminum oxide, boron nitride, and barium titanate are preferable, and silica is more preferable. The silica is not particularly limited, and examples thereof include crushed silica, spherical silica, and silica particles.

The inorganic filler may be an inorganic filler subjected to a surface treatment or an inorganic filler not subjected to a surface treatment. Examples of the surface treatment include treatment with a silane coupling agent.

Examples of the silane coupling agent include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, and an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 μm, more preferably 0.5 to 8 μm. Here, the average particle size refers to the volume average particle size. The volume average particle size can be measured by, for example, a laser diffraction method and the like.

### Curing Agent

The resin composition according to the present embodiment may contain a curing agent that reacts with at least one of the polyphenylene ether compound and the maleimide compound (A), if necessary, as long as the effects of the present invention are not impaired. Here, the curing agent refers to a compound that reacts with at least one of the polyphenylene ether compound and the maleimide compound (A) and contributes to curing of the resin composition. Examples of the curing agent include a maleimide compound (B) different from the maleimide compound (A), an epoxy compound, a methacrylate compound, an acrylate compound, a vinyl compound, a cyanate ester compound, an active ester compound, and an allyl compound.

The maleimide compound (B) is a maleimide compound that has a maleimide group in the molecule but does not have an arylene structure bonded in the meta-orientation in the molecule. Examples of the maleimide compound (B) include a maleimide compound having one or more maleimide groups in the molecule, and a modified maleimide compound. The maleimide compound (B) is not particularly limited as long as it is a maleimide compound that has one or more maleimide groups in the molecule but does not have an arylene structure bonded in the meta-orientation in the molecule. Specific examples of the maleimide compound (B) include phenylmaleimide compounds such as 4,4′-diphenylmethanebismaleimide, polyphenylmethanemaleimide, m-phenylenebismaleimide, bisphenol A diphenyl ether bismaleimide, 3,3′-dimethyl-5,5′-diethyl-4,4′-diphenylmethanebismaleimide, 4-methyl-1,3-phenylenebismaleimide, and a biphenylaralkyl type polymaleimide compound, and an N-alkylbismaleimide compound having an aliphatic skeleton. Examples of the modified maleimide compound include a modified maleimide compound in which a part of the molecule is modified with an amine compound and a modified maleimide compound in which a part of the molecule is modified with a silicone compound. As the maleimide compound (B), a commercially available product can also be used, and for example, the solid component in MIR-3000-70MT manufactured by Nippon Kayaku Co., Ltd., BMI-4000 and BMI-5100 manufactured by Daiwa Kasei Industry Co., Ltd., and BMI-689, BMI-1500, BMI-3000J and BMI-5000 manufactured by Designer Molecules Inc. may be used.

The epoxy compound is a compound having an epoxy group in the molecule, and specific examples thereof include a bisphenol type epoxy compound such as a bisphenol A type epoxy compound, a phenol novolac type epoxy compound, a cresol novolac type epoxy compound, a dicyclopentadiene type epoxy compound, a bisphenol A novolac type epoxy compound, a biphenylaralkyl type epoxy compound, and a naphthalene ring-containing epoxy compound. The epoxy compound also includes an epoxy resin, which is a polymer of each of the epoxy compounds.

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The vinyl compound is a compound having a vinyl group in the molecule, and examples thereof include a monofunctional vinyl compound (monovinyl compound) having one vinyl group in the molecule and a polyfunctional vinyl compound having two or more vinyl groups in the molecule. Examples of the polyfunctional vinyl compound include divinylbenzene, curable polybutadiene having a carbon-carbon unsaturated double bond in the molecule, and a curable butadiene-styrene copolymer having a carbon-carbon unsaturated double bond in the molecule.

The cyanate ester compound is a compound having a cyanato group in the molecule, and examples thereof include 2,2-bis(4-cyanatophenyl)propane, bis(3,5-dimethyl-4-cyanatophenyl)methane, and 2,2-bis(4-cyanatophenyl)ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

The allyl compound is a compound having an allyl group in the molecule, and examples thereof include a triallyl isocyanurate compound such as triallyl isocyanurate (TAIL), a diallyl bisphenol compound, and diallyl phthalate (DAP).

As the curing agent, the above curing agents may be used singly or in combination of two or more kinds thereof.

The weight average molecular weight of the curing agent is not particularly limited and is, for example, preferably 100 to 5000, more preferably 100 to 4000, still more preferably 100 to 3000. When the weight average molecular weight of the curing agent is too low, the curing agent may easily volatilize from the compounding component system of the resin composition. When the weight average molecular weight of the curing agent is too high, the viscosity of the varnish of the resin composition and the melt viscosity of the resin composition in the case of being in B stage become too high, and there is a risk of deterioration in moldability and deterioration in appearance after molding. Hence, a resin composition imparting superior heat resistance and moldability to its cured product is obtained when the weight average molecular weight of the curing agent is in such a range. It is considered that this is because the resin composition can be suitably cured. Here, the weight average molecular weight may be measured by a general molecular weight measurement method, and specific examples thereof include a value measured by gel permeation chromatography (GPC).

In the curing agent, the average number (number of functional groups) of the functional groups, which contribute to the reaction during curing of the resin composition, per one molecule of the curing agent varies depending on the weight average molecular weight of the curing agent but is, for example, preferably 1 to 20, more preferably 2 to 18. When this number of functional groups is too small, sufficient heat resistance of the cured product tends to be hardly attained. When the number of functional groups is too large, the reactivity is too high and, for example, troubles such as a decrease in the storage stability of the resin composition or a decrease in the fluidity of the resin composition may occur.

### Thermoplastic Styrenic Polymer

The resin composition according to the present embodiment may contain a thermoplastic styrenic polymer, if necessary, as long as the effects of the present invention are not impaired.

The thermoplastic styrenic polymer is, for example, a polymer obtained by polymerizing a monomer containing a styrenic monomer, and may be a styrenic copolymer. Examples of the styrenic copolymer include a copolymer obtained by copolymerizing one or more styrenic monomers and one or more other monomers copolymerizable with the styrenic monomers. The thermoplastic styrenic polymer may be a hydrogenated styrenic copolymer obtained by hydrogenating the styrenic copolymer.

The styrenic monomer is not particularly limited, but examples thereof include styrene, a styrene derivative, one in which some the hydrogen atoms of the benzene ring in styrene are substituted with an alkyl group, one in which some the hydrogen atoms of the vinyl group in styrene are substituted with an alkyl group, vinyltoluene, α-methylstyrene, butylstyrene, dimethylstyrene, and isopropenyltoluene. As the styrenic monomer, these may be used singly or in combination of two or more kinds thereof.

The other copolymerizable monomer is not particularly limited, but examples thereof include olefins such as α-pinene, β-pinene, and dipentene, 1,4-hexadiene and 3-methyl-1,4-hexadiene unconjugated dienes, and 1,3-butadiene and 2-methyl-1,3-butadiene (isoprene) conjugated dienes. As the other copolymerizable monomer, these may be used singly or in combination of two or more kinds thereof.

Examples of the styrenic copolymer include a methylstyrene (ethylene/butylene) methylstyrene copolymer, a methylstyrene (ethylene-ethylene/propylene) methylstyrene copolymer, a styrene isoprene copolymer, a styrene isoprene styrene copolymer, a styrene (ethylene/butylene) styrene copolymer, a styrene (ethylene-ethylene/propylene) styrene copolymer, a styrene butadiene styrene copolymer, a styrene (butadiene/butylene) styrene copolymer, and a styrene isobutylene styrene copolymer.

Examples of the hydrogenated styrenic copolymer include hydrogenated products of the styrenic copolymers. More specific examples of the hydrogenated styrenic copolymer include a hydrogenated methylstyrene (ethylene/butylene) methylstyrene copolymer, a hydrogenated methylstyrene (ethylene-ethylene/propylene) methylstyrene copolymer, a hydrogenated styrene isoprene copolymer, a hydrogenated styrene isoprene styrene copolymer, a hydrogenated styrene (ethylene/butylene) styrene copolymer, and a hydrogenated styrene (ethylene-ethylene/propylene) styrene copolymer.

The thermoplastic styrenic polymers may be used singly or in combination of two or more kinds thereof.

The weight average molecular weight of thermoplastic styrenic polymer is preferably 1,000 to 300,000, more preferably 1,200 to 200,000. When the molecular weight is too low, the glass transition temperature or heat resistance of the cured product of the resin composition tends to decrease. When the molecular weight is too high, the viscosity of the resin composition when prepared in the form of a varnish and the viscosity of the resin composition during heat molding tend to be too high. The weight average molecular weight is only required to be one measured by a general molecular weight measurement method, and specific examples thereof include a value measured by gel permeation chromatography (GPC).

### Content

The content of the maleimide compound (A) is preferably 1 to 90 parts by mass, more preferably 5 to 80 parts by mass, still more preferably 20 to 50 parts by mass with respect to 100 parts by mass of the total mass of the polyphenylene ether compound and the maleimide compound (A). In other words, the content of the polyphenylene ether compound is preferably 10 to 99 parts by mass, more preferably 20 to 95 parts by mass, still more preferably 50 to 80 parts by mass with respect to 100 parts by mass of the total mass of the polyphenylene ether compound and the maleimide compound (A). When the content of the maleimide compound (A) is too low, there is a tendency that the effect attained by addition of the maleimide compound (A) is unlikely to be exerted, and for example, the coefficient of thermal expansion cannot be sufficiently decreased or excellent heat resistance is unlikely to be maintained. When the content of the maleimide compound (A) is too low or too high, the adhesive properties to a metal foil tend to decrease. For these reasons, when the content of each of the maleimide compound (A) and the polyphenylene ether compound is in the above range, a resin composition is obtained which affords a cured product that exhibits excellent low dielectric properties and heat resistance, has a low coefficient of thermal expansion, and exhibits superior adhesive properties to a metal foil.

The content of the inorganic filler is preferably 10 to 250 parts by mass, more preferably 40 to 200 parts by mass with respect to 100 parts by mass of the total mass of the polyphenylene ether compound and the maleimide compound (A).

As described above, the resin composition may contain a curing agent and a thermoplastic styrenic polymer. In a case where the resin composition contains the curing agent, the content of the curing agent is preferably 1 to 50 parts by mass, more preferably 5 to 40 parts by mass with respect to 100 parts by mass of the total mass of the polyphenylene ether compound and the maleimide compound (A). In a case where the resin composition contains the thermoplastic styrenic polymer, the content of the thermoplastic styrenic polymer is preferably 1 to 50 parts by mass, more preferably 5 to 40 parts by mass with respect to 100 parts by mass of the total mass of the polyphenylene ether compound and the maleimide compound (A).

### Other Components

The resin composition according to the present embodiment may contain components (other components) other than the polyphenylene ether compound, the maleimide compound (A), and the inorganic filler, if necessary, as long as the effects of the present invention are not impaired. As the other components contained in the resin composition according to the present embodiment, for example, additives such as a reaction initiator, a reaction accelerator, a catalyst, a polymerization retarder, a polymerization inhibitor, a dispersant, a leveling agent, a silane coupling agent, an antifoaming agent, an antioxidant, a heat stabilizer, an antistatic agent, an ultraviolet absorber, a dye or pigment, and a lubricant may be further contained in addition to the curing agent and thermoplastic styrenic polymer as described above.

As described above, the resin composition according to the present embodiment may contain a reaction initiator. The reaction initiator is not particularly limited as long as it can promote the curing reaction of the resin composition, and examples thereof include a peroxide and an organic azo compound. Examples of the peroxide include α,α′-bis(t-butylperoxy-m-isopropyl)benzene, 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among these, α,α′-bis(t-butylperoxy-m-isopropyl)benzene is preferably used. α,α′-Bis(t-butylperoxy-m-isopropyl)benzene has a relatively high reaction initiation temperature and thus can suppress the promotion of the curing reaction at the time point at which curing is not required, for example, at the time of prepreg drying, and can suppress a decrease in storage stability of the resin composition. α,α′-Bis(t-butylperoxy-m-isopropyl)benzene exhibits low volatility, thus does not volatilize at the time of prepreg drying and storage, and exhibits favorable stability. The reaction initiators may be used singly or in combination of two or more thereof.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among these, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene which have a melting point of 300° C. or more are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, and a phosphinate-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the phosphinate-based flame retardant include metal phosphinates such as an aluminum dialkyl phosphinate. As the flame retardant, the respective flame retardants exemplified may be used singly or in combination of two or more kinds thereof.

### Production Method

The method for producing the resin composition is not particularly limited, and examples thereof include a method in which the polyphenylene ether compound, the maleimide compound (A), and the inorganic filler are mixed together so as to have predetermined contents. Examples thereof include the method to be described later in the case of obtaining a varnish-like composition containing an organic solvent.

Moreover, by using the resin composition according to the present embodiment, a prepreg, a metal-clad laminate, a wiring board, a metal foil with resin, and a film with resin can be obtained as described below.

### Prepreg

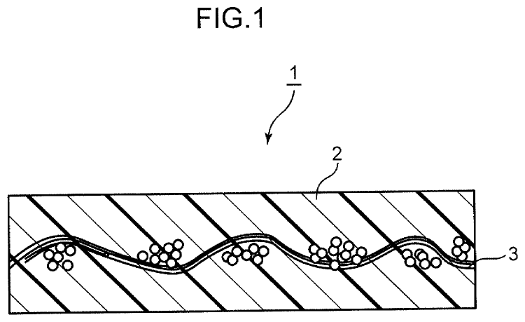

FIG. 1 is a schematic sectional view illustrating an example of a prepreg 1 according to an embodiment of the present invention.

As illustrated in FIG. 1, the prepreg I according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state in which the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the polyphenylene ether compound, the curing agent, and the like, and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, but examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 80° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition, which affords a cured product exhibiting excellent low dielectric properties, heat resistance, and adhesive properties to a metal foil and a low coefficient of thermal expansion. For this reason, the prepreg including this resin composition or a semi-cured product of this resin composition is a prepreg, which affords a cured product exhibiting excellent low dielectric properties, heat resistance, and adhesive properties to a metal foil and a low coefficient of thermal expansion. Moreover, a wiring board including an insulating layer containing a cured product, which exhibits excellent low dielectric properties, heat resistance, and adhesive properties to a metal foil and a low coefficient of thermal expansion, can be suitably manufactured using this prepreg.

### Metal-Clad Laminate

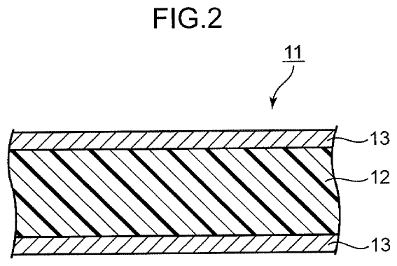

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μ. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170° C. to 220° C., the pressure to 3 to 4 MPa, and the time to 60 to 150 minutes. Moreover, the metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition, which affords a cured product exhibiting excellent low dielectric properties, heat resistance, and adhesive properties to a metal foil and a low coefficient of thermal expansion. For this reason, the metal-clad laminate including an insulating layer containing the cured product of this resin composition is a metal-clad laminate including an insulating layer containing a cured product, which exhibits excellent low dielectric properties, heat resistance, and adhesive properties to a metal foil and a low coefficient of thermal expansion. Moreover, a wiring board including an insulating layer containing a cured product, which exhibits excellent low dielectric properties, heat resistance, and adhesive properties to a metal foil and a low coefficient of thermal expansion, can be suitably manufactured using this metal-clad laminate.

### Wiring Board

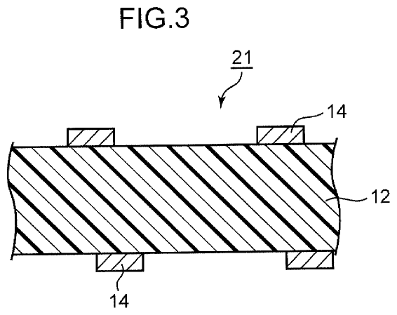

FIG. 3 is a schematic sectional view illustrating an example of a wiring board 21 according to an embodiment of the present invention.

As illustrated in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above. The wiring board 21 is a wiring board including an insulating layer 12 containing a cured product, which exhibits excellent low dielectric properties, heat resistance, and adhesive properties to a metal foil and a low coefficient of thermal expansion.

### Metal Foil With Resin

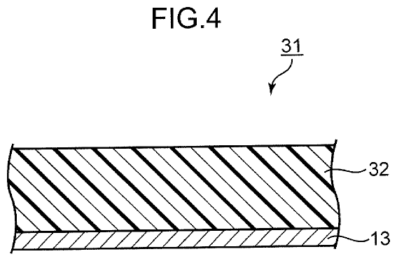

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 80° C. or more and 180° C. or less and 1 minute or more and 10 minutes or less. The heated resin composition is formed as the uncured resin layer 32 on the metal foil 13. By the heating, the organic solvent can be decreased or removed by being volatilized from the resin varnish.

The resin composition according to the present embodiment is a resin composition, which affords a cured product exhibiting excellent low dielectric properties, heat resistance, and adhesive properties to a metal foil and a low coefficient of thermal expansion. For this reason, the metal foil with resin including a resin layer containing this resin composition or a semi-cured product of this resin composition is a metal foil with resin including a resin layer, which affords a cured product exhibiting excellent low dielectric properties, heat resistance, and adhesive properties to a metal foil and a low coefficient of thermal expansion. Moreover, this metal foil with resin can be used in the manufacture of a wiring board including an insulating layer containing a cured product, which exhibits excellent low dielectric properties, heat resistance, and adhesive properties to a metal foil and a low coefficient of thermal expansion. For example, by laminating the metal foil with resin on a wiring board, a multilayer wiring board can be manufactured. As a wiring board obtained using such a metal foil with resin, there is obtained a wiring board including an insulating layer containing a cured product, which exhibits excellent low dielectric properties, heat resistance, and adhesive properties to a metal foil and a low coefficient of thermal expansion.

### Film With Resin

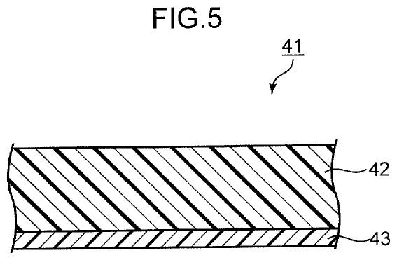

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyimide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 80° C. or more and 180° C. or less and 1 minute or more and 10 minutes or less. The heated resin composition is formed as the uncured resin layer 42 on the support film 43. By the heating, the organic solvent can be decreased or removed by being volatilized from the resin varnish.

The resin composition according to the present embodiment is a resin composition, which affords a cured product exhibiting excellent low dielectric properties, heat resistance, and adhesive properties to a metal foil and a low coefficient of thermal expansion. For this reason, the film with resin including a resin layer containing this resin composition or a semi-cured product of this resin composition is a film with resin including a resin layer, which affords a cured product exhibiting excellent low dielectric properties, heat resistance, and adhesive properties to a metal foil and a low coefficient of thermal expansion. Moreover, this film with resin can be used in the manufacture of a wiring board including an insulating layer containing a cured product, which exhibits excellent low dielectric properties, heat resistance, and adhesive properties to a metal foil and a low coefficient of thermal expansion. A multilayer wiring board can be manufactured, for example, by laminating the film with resin on a wiring board and then peeling off the support film from the film with resin or by peeling off the support film from the film with resin and then laminating the film with resin on a wiring board. As a wiring board obtained using such a film with resin, there is obtained a wiring board including an insulating layer containing a cured product, which exhibits excellent low dielectric properties, heat resistance, and adhesive properties to a metal foil and a low coefficient of thermal expansion.

According to the present invention, it is possible to provide a resin composition, which affords a cured product exhibiting excellent low dielectric properties, heat resistance, and adhesive properties to a metal foil and a low coefficient of thermal expansion. In addition, according to the present invention, a prepreg, a film with resin, a metal foil with resin, a metal-clad laminate, and a wiring board which are obtained using the resin composition are provided.

Hereinafter, the present invention will be described more specifically with reference to examples, but the scope of the present invention is not limited thereto.

### EXAMPLES

### Examples 1 to 25 and Comparative Examples 1 to 6

The respective components to be used when preparing a resin composition in the present examples will be described.

### Polyphenylene Ether Compound: PPE

Modified PPE-1: Polyphenylene ether compound having vinylbenzyl group (ethenylbenzyl group) at terminal (OPE-2st 1200 manufactured by MITSUBISHI GAS CHEMICAL COMPANY, a modified polyphenylene ether compound, which has Mn of 1200 and is represented by Formula (12), where Ar₂ is a phenylene group, R₁ to R₃ are a hydrogen atom, and p is 1)
Modified PPE-2: Polyphenylene ether compound having vinylbenzyl group (ethenylbenzyl group) at terminal (OPE-2st 2200 manufactured by MITSUBISHI GAS CHEMICAL COMPANY, a modified polyphenylene ether compound, which has Mn of 2200 and is represented by Formula (12), where Ar₂ is a phenylene group, R₁ to R₃ are a hydrogen atom, and p is 1)
Modified PPE-3: Polyphenylene ether compound having vinylbenzyl group (ethenylbenzyl group) at terminal (a modified polyphenylene ether compound obtained by reacting polyphenylene ether with chloromethylstyrene)

Specifically, this is a modified polyphenylene ether compound obtained by conducting a reaction as follows.

First, 200 g of polyphenylene ether (SA90 manufactured by SABIC Innovative Plastics Co., Ltd., number of terminal hydroxyl groups: 2, weight average molecular weight Mw: 1700), 30 g of a mixture containing p-chloromethylstyrene and m-chloromethylstyrene at a mass ratio of 50:50 (chloromethylstyrene: CMS manufactured by Tokyo Chemical Industry Co., Ltd.), 1.227 g of tetra-n-butylammonium bromide as a phase transfer catalyst, and 400 g of toluene were introduced into a 1-liter three-necked flask equipped with a temperature controller, a stirrer, cooling equipment, and a dropping funnel and stirred. Then, the mixture was stirred until polyphenylene ether, chloromethylstyrene, and tetra-n-butylammonium bromide were dissolved in toluene. At that time, the mixture was gradually heated until the liquid temperature finally reached 75° C. Thereafter, an aqueous sodium hydroxide solution (20 g of sodium hydroxide/20 g of water) as an alkali metal hydroxide was added dropwise to the solution over 20 minutes. Thereafter, the mixture was further stirred at 75° C. for 4 hours. Next, the resultant in the flask was neutralized with hydrochloric acid at 10% by mass and then a large amount of methanol was added into the flask. By doing so, a precipitate was generated in the liquid in the flask. In other words, the product contained in the reaction solution in the flask was reprecipitated. Thereafter, this precipitate was taken out by filtration, washed three times with a mixed solution of methanol and water contained at a mass ratio of 80:20, and then dried under reduced pressure at 80° C. for 3 hours.

The obtained solid was analyzed by ¹H-NMR (400 MHz, CDCl₃, TMS). As a result of NMR measurement, a peak attributed to a vinylbenzyl group (ethenylbenzyl group) was observed at 5 to 7 ppm. This made it possible to confirm that the obtained solid was a modified polyphenylene ether compound having a vinylbenzyl group (ethenylbenzyl group) as the substituent at the molecular terminal in the molecule. Specifically, it was confirmed that the obtained solid was ethenylbenzylated polyphenylene ether. This modified polyphenylene ether compound obtained was a modified polyphenylene ether compound represented by Formula (13), where Y was a dimethylmethylene group (a group represented by Formula (11), where R₃₃ and R₃₄ were a methyl group), Ar₁ was a phenylene group, R₁ to R₃ were a hydrogen atom, and p was 1.

The number of terminal functional groups in the modified polyphenylene ether was measured as follows.

First, the modified polyphenylene ether was accurately weighed. The weight at that time is defined as X (mg). Thereafter, this modified polyphenylene ether weighed was dissolved in 25 mL of methylene chloride, 100 μL of an ethanol solution of tetraethylammonium hydroxide (TEAH) at 10% by mass (TEAH : ethanol (volume ratio)=15:85) was added to the solution, and then the absorbance (Abs) of this mixture at 318 nm was measured using a UV spectrophotometer (UV-1600 manufactured by Shimadzu Corporation). Then, the number of terminal hydroxyl groups in the modified polyphenylene ether was calculated from the measurement results using the following equation.

Residual OH amount (μmol/g)=[(25×Abs)/(ε×OPL×X)]×10⁶

Here, ε indicates the extinction coefficient and is 4700 L/mol·cm. OPL indicates the cell path length and is 1 cm.

Since the calculated residual OH amount (the number of terminal hydroxyl groups) in the modified polyphenylene ether is almost zero, it was found that the hydroxyl groups in the polyphenylene ether before being modified are almost modified. From this fact, it was found that the number of terminal hydroxyl groups decreased from the number of terminal hydroxyl groups in polyphenylene ether before being modified is the number of terminal hydroxyl groups in polyphenylene ether before being modified. In other words, it was found that the number of terminal hydroxyl groups in polyphenylene ether before being modified is the number of terminal functional groups in the modified polyphenylene ether. In other words, the number of terminal functional groups was two.

In addition, the intrinsic viscosity (IV) of the modified polyphenylene ether was measured in methylene chloride at 25° C. Specifically, the intrinsic viscosity (IV) of the modified polyphenylene ether was measured in a methylene chloride solution (liquid temperature: 25° C.) of the modified polyphenylene ether at 0.18 g/45 ml using a viscometer (AVS500 Visco System manufactured by SCHOTT Instruments GmbH). As a result, the intrinsic viscosity (IV) of the modified polyphenylene ether was 0.086 dl/g.

The molecular weight distribution of the modified polyphenylene ether was measured by GPC. Moreover, the weight average molecular weight (Mw) was calculated from the obtained molecular weight distribution. As a result, Mw was 1900.
Modified PPE-4: Modified polyphenylene ether obtained by modifying terminal hydroxyl group of polyphenylene ether with methacryl group (a modified polyphenylene ether compound represented by Formula (14), where Y is a dimethylmethylene group (a group represented by Formula (11), where R₃₃ and R₃₄ are a methyl group), SA9000 manufactured by SABIC Innovative Plastics Co., Ltd., weight average molecular weight Mw: 2000, number of terminal functional groups: 2)
Unmodified PPE: Polyphenylene ether (PPE) (SA90 manufactured by SABIC Innovative Plastics Co., Ltd., intrinsic viscosity (IV): 0.083 dl/g, number of terminal hydroxyl groups: 2, weight average molecular weight Mw: 1700)

### Maleimide Compound (A)

Maleimide compound (A): Maleimide compound having arylene structure bonded in meta-orientation in molecule (solid component in MIR-5000-60T (maleimide compound dissolved in toluene) manufactured by Nippon Kayaku Co., Ltd., maleimide compound (A2) represented by Formula (2))

### Inorganic Filler

Silica: Silica particles subjected to surface treatment with silane coupling agent having phenylamino group in molecule (SC2500-SXJ manufactured by Admatechs Company Limited)

### Curing Agent

Epoxy compound: Dicyclopentadiene type epoxy resin (HP-7200 manufactured by DIC Corporation)
Maleimide compound (B)-1: Maleimide compound not having arylene structure bonded in meta-orientation in molecule (solid component in MIR-3000-70MT (maleimide compound dissolved in methyl ethyl ketone-toluene mixed solvent) manufactured by Nippon Kayaku Co., Ltd., biphenylaralkyl type maleimide compound)
Maleimide compound (B)-2: Maleimide compound not having arylene structure bonded in meta-orientation in molecule (BMI-689 manufactured by Designer Molecules Inc., N-alkyl bismaleimide compound)
Maleimide compound (B)-3: Maleimide compound not having arylene structure bonded in meta-orientation in molecule (BMI-1500 manufactured by Designer Molecules Inc., N-alkyl bismaleimide compound)
Maleimide compound (B)-4: Maleimide compound not having arylene structure bonded in meta-orientation in molecule (BMI-4000 manufactured by Daiwa Kasei Industry Co., Ltd.)
Allyl compound: Triallyl isocyanurate (TAIC) (TRIC manufactured by Nihon Kasei CO., LTD.)

Methacrylate compound: Tricyclodecane dimethanol dimethacrylate (NK Ester DCP manufactured by SHIN-NAKAMURA CHEMICAL Co., Ltd.)

Polyfunctional vinyl compound: Liquid curable butadiene-styrene copolymer having carbon-carbon unsaturated double bond in molecule (Ricon181 manufactured by CRAY VALLEY)

### Thermoplastic Styrenic Polymer

V9827: Hydrogenated methylstyrene (ethylene/butylene) methylstyrene copolymer (V9827 manufactured by Kuraray Co., Ltd., weight average molecular weight Mw: 92,000)
FTR_{6125:} Styrenic polymer (FTR₆₁₂₅ manufactured by Mitsui Chemicals, Inc., weight average molecular weight Mw: 1950, number average molecular weight Mn: 1150)

### Reaction Initiator

PBP: α,α′-Di(t-butylperoxy)diisopropylbenzene (Perbutyl P (PBP) manufactured by NOF CORPORATION)

### Reaction Accelerator

2E4MZ: 2-Ethyl-4-methylimidazole (2E4MZ manufactured by SHIKOKU CHEMICALS CORPORATION)

### Preparation Method

Varnish-like resin compositions (varnishes) according to Examples 1 to 17, Examples 19 to 24, and Comparative Examples 1 to 6 were prepared as follows. First, the respective components other than the inorganic filler were added to and mixed in toluene at the compositions (parts by mass) presented in Tables 1 to 3 so that the solid concentration was 50% by mass. The mixture was stirred for 60 minutes. Thereafter, the filler was added to the obtained liquid, and the inorganic filler was dispersed in the liquid using a bead mill. By doing so, a varnish-like resin composition (varnish) was obtained. As the varnish-like resin compositions (varnishes) according to Examples 18 and 25, varnish-like resin compositions (varnishes) were obtained in the same manner as the method for preparing a varnish-like resin composition according to Example 1 except that methyl ethyl ketone was used instead of toluene.

Next, a prepreg and an evaluation substrate (metal-clad laminate) were obtained as follows.

The obtained varnish was impregnated into a fibrous base material (glass cloth: #1067 type, E glass manufactured by Nitto Boseki Co., Ltd.) and then heated and dried at 130° C. for 3 minutes, thereby fabricating a prepreg. At that time, the content (resin content) of the components constituting the resin composition with respect to the prepreg was adjusted to be 74% by mass by the curing reaction.

Next, an evaluation substrate (metal-clad laminate) was obtained as follows.

Eleven sheets of each prepreg obtained were stacked, and a copper foil (GTH-MP manufactured by FURUKAWA CIRCUIT FOIL TAIWAN CORPORATION, thickness: 12 μm) was disposed on both sides of the stacked body. This as a body to be pressed was heated to a temperature of 200° C. at a rate of temperature rise of 3 ° C./min and heated and pressed under the conditions of 200° C., 120 minutes, and a pressure of 4 MPa, thereby obtaining an evaluation substrate (metal-clad laminate) having a copper foil bonded to both surfaces and a thickness of about 830 μm.

The prepregs and evaluation substrates (metal-clad laminates) fabricated as described above were evaluated by the following methods.

### Coefficient of Thermal Expansion

Using an unclad substrate obtained by removing the copper foil from the evaluation substrate (metal-clad laminate) by etching as a test piece, the coefficient of thermal expansion (CTEz: ppm/° C.) in the Z-axis direction of the base material was measured in a temperature region less than the glass transition temperature of the cured product of the resin composition by TMA (thermo-mechanical analysis) in conformity with IPC-TM-650 2.4.24. For the measurement, a TMA instrument (TMA6000 manufactured by SII NanoTechnology Inc.) was used, and the measurement was performed in a range of 30° C. to 320° C.

### Glass Transition Temperature (Tg)

Using an unclad substrate obtained by removing the copper foil from the evaluation substrate (metal-clad laminate) by etching as a test piece, the Tg of the cured product of the resin composition was measured by a viscoelastic spectrometer “DMS6100” manufactured by Seiko Instruments Inc. At this time, dynamic viscoelasticity measurement (DMA) was performed with a tensile module at a frequency of 10 Hz, and the temperature at which tan S was maximized when the temperature was raised from room temperature to 320° C. at a rate of temperature rise of 5° C./min was taken as Tg (° C.).

### Peel Strength

The copper foil was peeled off from the evaluation substrate (metal-clad laminate), and the peel strength at that time was measured in conformity with JIS C 6481 (1996). Specifically, a pattern having a width of 10 mm and a length of 100 mm was formed on the evaluation substrate, the copper foil was peeled off at a speed of 50 mm/min using a tensile tester, and the peel strength (N/mm) at that time was measured.

### Heat Resistance

The heat resistance of the evaluation substrate (metal-clad laminate) was measured in conformity with the standard of JIS C 6481 (1996). Specifically, the evaluation substrate (metal-clad laminate) cut into a predetermined size was used as a test piece, and this test piece was left for 1 hour in thermostatic chambers set to 280° C., 290° C., and 300° C., respectively, and then taken out. The presence or absence of blistering on the test piece subjected to a heat treatment in this manner was visually observed. It was evaluated as “Very Good” when blistering was not confirmed after the heat treatment in a thermostatic chamber set to 300° C. It was evaluated as “Good” when blistering was confirmed after the heat treatment in a thermostatic chamber set to 300° C. but blistering was not confirmed after the heat treatment in a thermostatic chamber set to 290° C. It was evaluated as “Fair” when blistering was confirmed after the heat treatment in a thermostatic chamber set to 290° C. but blistering was not confirmed after the heat treatment in a thermostatic chamber set to 280° C. It was evaluated as “Poor” when blistering was confirmed after the heat treatment in a thermostatic chamber set to 280° C.

### Dielectric Properties (Relative Dielectric Constant and Dielectric Loss Tangent)

The relative dielectric constant and dielectric loss tangent at 10 GHz were measured by the cavity perturbation method using an unclad substrate obtained by removing the copper foil from the evaluation substrate (metal-clad laminate) by etching as a test piece. Specifically, the relative dielectric constant and dielectric loss tangent of the evaluation substrate at 10 GHz were measured using a network analyzer (N5230A manufactured by Keysight Technologies).

The results of each of the evaluations are presented in Tables 1 to 3.

TABLE 1

| | | | Example | | | | | |
|---|---|---|---|---|---|---|---|---|
| | | | 1 | 2 | 3 | 4 | 5 | |
| Composition | PPE | Modified PPE-1 | 60 | 60 | — | — | — | |
| (parts by | | Modified PPE-2 | — | — | 60 | — | — | |
| mass) | | Modified PPE-3 | — | — | — | 60 | — | |
| | | Modified PPE-4 | — | — | — | — | 60 | |
| | | Unmodified PPE | — | — | — | — | — | |
| | Maleimide | Maleimide | 40 | 40 | 40 | 40 | 40 | |
| | compound | compound (A) | | | | | | |
| | Inorganic filler | Silica | 128.0 | 128.0 | 128.0 | 128.0 | 128.0 | |
| | Curing agent | Maleimide | — | — | — | — | — | |
| | | compound (B)-1 | | | | | | |
| | Reaction initiator | PBP | — | 1 | 1 | 1 | 1 | |
| | Reaction | 2E4MZ | — | — | — | — | — | |
| | accelerator | | | | | | | |
| Evaluation | Coefficient of thermal | | 40 | 40 | 40 | 40 | 40 | |
| | expansion (ppm/° C.) | | | | | | | |
| | Glass transition | | 260 | 265 | 265 | 265 | 265 | |
| | temperature Tg (° C.) | | | | | | | |
| | Peel strength (N/mm) | | 0.70 | 0.70 | 0.70 | 0.70 | 0.70 | |
| | Heat resistance | | Good | Very | Very | Very | Very | |
| | | | | Good | Good | Good | Good | |
| | Dielectric | Relative | 3.5 | 3.5 | 3.5 | 3.5 | 3.5 | |
| | properties | dielectric constant | | | | | | |
| | | Dielectric | 0.0039 | 0.0041 | 0.0041 | 0.0041 | 0.0042 | |
| | | loss tangent | | | | | | |
| | | | Commparative Example | | | | | |
| | | | 1 | 2 | 3 | 4 | 5 | 6 |
| Composition | PPE | Modified PPE-1 | 60 | — | — | 60 | 100 | — |
| (parts by | | Modified PPE-2 | — | — | — | — | — | — |
| mass) | | Modified PPE-3 | — | — | — | — | — | — |
| | | Modified PPE-4 | — | — | — | — | — | — |
| | | Unmodified PPE | — | 60 | 60 | — | — | — |
| | Maleimide | Maleimide | — | 40 | 40 | 40 | — | 100 |
| | compound | compound (A) | | | | | | |
| | Inorganic filler | Silica | 128.0 | 128.0 | 128.0 | — | 128.0 | 128.0 |
| | Curing agent | Maleimide | 40 | — | — | — | — | — |
| | | compound (B)-1 | | | | | | |
| | Reaction initiator | PBP | 1 | 1 | — | 1 | 1 | 1 |
| | Reaction | 2E4MZ | — | — | 0.5 | — | — | — |
| | accelerator | | | | | | | |
| Evaluation | Coefficient of thermal | | 40 | 45 | 40 | 60 | 50 | 30 |
| | expansion (ppm/° C.) | | | | | | | |
| | Glass transition | | 270 | 230 | 250 | 270 | 210 | 290 |
| | temperature Tg (° C.) | | | | | | | |
| | Peel strength (N/mm) | | 0.60 | 0.35 | 0.60 | 0.80 | 0.55 | 0.45 |
| | Heat resistance | | Very | Poor | Very | Good | Fair | Very |
| | | | Good | | Good | | | Good |
| | Dielectric | Relative | 3.6 | 3.8 | 3.8 | 3.4 | 3.5 | 3.5 |
| | properties | dielectric constant | | | | | | |
| | | Dielectric | 0.0045 | 0.0070 | 0.0070 | 0.0047 | 0.0040 | 0.0043 |
| | | loss tangent | | | | | | |

TABLE 2

| | | | Example | | | | | | | |
|---|---|---|---|---|---|---|---|---|---|---|
| | | | 6 | 7 | 8 | 9 | 10 | 11 | 12 | 13 |
| Composition | PPE | Modified PPE-1 | 99 | 95 | 80 | 70 | 50 | 20 | 10 | 5 |
| (parts by | Maleimide | Maleimide | 1 | 5 | 20 | 30 | 50 | 80 | 90 | 95 |
| mass) | compound | compound (A) | | | | | | | | |
| | Inorganic filler | Silica | 128.0 | 128.0 | 128.0 | 128.0 | 128.0 | 128.0 | 128.0 | 128.0 |
| | Reaction initiator | PBP | 1 | 1 | 1 | 1 | 1 | 1 | 1 | 1 |
| Evaluation | Coefficient of thermal | | 48 | 45 | 43 | 42 | 35 | 32 | 30 | 30 |
| | expansion (ppm/° C.) | | | | | | | | | |
| | Glass transition | | 220 | 230 | 250 | 260 | 275 | 280 | 285 | 290 |
| | temperature Tg (° C.) | | | | | | | | | |
| | Peel strength (N/mm) | | 0.60 | 0.65 | 0.70 | 0.70 | 0.65 | 0.60 | 0.50 | 0.48 |
| | Heat resistance | | Good | Very | Very | Very | Very | Very | Very | Very |
| | | | | Good | Good | Good | Good | Good | Good | Good |
| | Dielectric | Relative | 3.5 | 3.5 | 3.5 | 3.5 | 3.5 | 3.5 | 3.5 | 3.5 |
| | properties | dielectric | | | | | | | | |
| | | constant | | | | | | | | |
| | | Dielectric | 0.0040 | 0.0040 | 0.0041 | 0.0041 | 0.0041 | 0.0042 | 0.0042 | 0.0043 |
| | | loss tangent | | | | | | | | |

TABLE 3

| | | | Example | | | | | |
|---|---|---|---|---|---|---|---|---|
| | | | 14 | 15 | 16 | 17 | 18 | 19 |
| Composition | PPE | Modified PPE-1 | 60 | 60 | 60 | 60 | 60 | 60 |
| (parts by | Maleimide compound | Maleimide compound (A) | 40 | 40 | 40 | 40 | 40 | 40 |
| mass) | Inorganic filler | Silica | 134.4 | 140.8 | 160.0 | 140.8 | 140.8 | 140.8 |
| | Curing agent | Epoxy compound | 5 | — | — | — | — | — |
| | | Maleimide compound (B)-2 | — | 10 | 25 | — | — | — |
| | | Maleimide compound (B)-3 | — | — | — | 10 | — | — |
| | | Maleimide compound (B)-4 | — | — | — | — | 10 | — |
| | | Allyl compound | — | — | — | — | — | 10 |
| | | Methacrylate compound | — | — | — | — | — | — |
| | | Polyfunctional | — | — | — | — | — | — |
| | | vinyl compound | | | | | | |
| | Thermoplastic | V9827 | — | — | — | — | — | — |
| | styrenic polymer | FTR6125 | — | — | — | — | — | — |
| | Reaction initiator | PBP | 1 | 1 | 1 | 1 | 1 | 1 |
| | Reaction accelerator | 2E4MZ | 0.01 | — | — | — | — | — |
| Evaluation | Coefficient of thermal expansion (ppm/° C.) | | 40 | 42 | 46 | 43 | 40 | 40 |
| | Glass transition temperature Tg (° C.) | | 265 | 250 | 235 | 250 | 275 | 270 |
| | Peel strength (N/mm) | | 0.73 | 0.75 | 0.78 | 0.76 | 0.70 | 0.70 |
| | Heat resistance | | Very | Very | Very | Very | Very | Very |
| | | | Good | Good | Good | Good | Good | Good |
| | | | 3.5 | 3.4 | 3.3 | 3.4 | 3.5 | 3.5 |
| | | | 0.0042 | 0.0036 | 0.0033 | 0.0035 | 0.0042 | 0.0043 |
| | | | Example | | | | | |
| | | | 20 | 21 | 22 | 23 | 24 | 25 |
| Composition | PPE | Modified PPE-1 | 60 | 60 | 60 | 60 | 60 | 60 |
| (parts by | Maleimide compound | Maleimide compound (A) | 40 | 40 | 40 | 40 | 40 | 40 |
| mass) | Inorganic filler | Silica | 140.8 | 140.8 | 140.8 | 140.8 | 140.8 | 140.8 |
| | Curing agent | Epoxy compound | — | — | — | — | — | — |
| | | Maleimide compound (B)-2 | — | — | — | — | 5 | — |
| | | Maleimide compound (B)-3 | — | — | — | — | — | — |
| | | Maleimide compound (B)-4 | — | — | — | — | — | 5 |
| | | Allyl compound | — | — | — | — | — | — |
| | | Methacrylate compound | 10 | — | — | — | — | — |
| | | Polyfunctional | — | 10 | — | — | — | — |
| | | vinyl compound | | | | | | |
| | Thermoplastic | V9827 | — | — | 10 | — | — | — |
| | styrenic polymer | FTR6125 | — | — | — | 10 | 5 | 5 |
| | Reaction initiator | PBP | 1 | 1 | 1 | 1 | 1 | 1 |
| | Reaction accelerator | 2E4MZ | — | — | — | — | — | — |
| Evaluation | Coefficient of thermal expansion (ppm/° C.) | | 40 | 40 | 42 | 42 | 42 | 40 |
| | Glass transition temperature Tg (° C.) | | 270 | 260 | 255 | 250 | 250 | 270 |
| | Peel strength (N/mm) | | 0.70 | 0.67 | 0.65 | 0.65 | 0.70 | 0.70 |
| | Heat resistance | | Very | Very | Very | Very | Very | Very |
| | | | Good | Good | Good | Good | Good | Good |
| | Dielectric properties | Relative dielectric constant | 3.5 | 3.4 | 3.4 | 3.4 | 3.4 | 3.5 |
| | | Dielectric loss tangent | 0.0043 | 0.0035 | 0.0035 | 0.0035 | 0.0036 | 0.0039 |

As can be seen from Tables 1 to 3, in resin compositions containing a polyphenylene ether compound having a carbon-carbon unsaturated double bond in the molecule, in the case of using resin compositions (Examples 1 to 25) containing a maleimide compound having an arylene structure bonded in the meta-orientation in the molecule (maleimide compound (A)) and an inorganic filler, cured products having a lower coefficient of thermal expansion, a higher peel strength, excellent heat resistance such as a higher glass transition temperature, a lower dielectric constant and a lower dielectric loss tangent were obtained as compared to the case of not using these resin compositions. Specifically, the cured product obtained using the resin composition according to Example 2 had a lower relative dielectric constant, a lower dielectric loss tangent and a higher peel strength as compared to the cure product obtained using the resin composition according to Comparative Example 1, which was the same as the resin composition according to Example 2 except that the resin composition contained a maleimide compound (B)-1 not having an arylene structure bonded in the meta-orientation in the molecule instead of the maleimide compound (A) as a maleimide compound. The cured product obtained using the resin composition according to Example 2 had a higher peel strength, excellent heat resistance such as a higher glass transition temperature, a lower relative dielectric constant and a lower dielectric loss tangent as compared to the case (Comparative Example 2) of using an unmodified PPE instead of a polyphenylene ether compound having a carbon-carbon unsaturated double bond in the molecule. In the case (Comparative Example 3) of using unmodified PPE and a reaction accelerator, the peel strength and heat resistance increase as compared to those of Comparative Example 2. Even so, the cured product obtained using the resin composition according to Example 2 had a lower relative dielectric constant and a lower dielectric loss tangent as compared to that of Comparative Example 3. The cured product obtained using the resin composition according to Example 2 had not only a lower coefficient of thermal expansion but also lower dielectric properties as compared to the cure product obtained using the resin composition according to Comparative Example 1, which was the same as the resin composition according to Example 2 except that the resin composition did not contain contained an inorganic filler. The cured product obtained using the resin composition according to Example 2 had not only lower heat resistance such as a lower glass transition temperature but also a lower coefficient of thermal expansion as compared to the cure product obtained using the resin composition not containing a maleimide compound according to Comparative Example 5. The cured product obtained using the resin composition according to Example 2 had a higher peel strength as compared to the cure product obtained using the resin composition not containing a polyphenylene ether compound having a carbon-carbon unsaturated double bond in the molecule according to Comparative Example 6. From these facts, it has been found that the resin compositions according to Examples 1 to 25 afford cured products having a low coefficient of thermal expansion, a high peel strength, excellent heat resistance such as a high glass transition temperature, a low dielectric constant and a low dielectric loss tangent.

In a case (Examples 6 to 12) where the content of the maleimide compound (A) was 1 to 90 parts by mass with respect to 100 parts by mass of the total mass of the polyphenylene ether compound and the maleimide compound (A), the peel strength was higher as compared to the case (Example 13) where the content of the maleimide compound (A) exceeded 90 parts by mass. From this fact, it has been found that it is preferable that the content of the maleimide compound (A) is 1 to 90 parts by mass from the viewpoint of enhancing the adhesive properties to a copper foil. From Table 3, it has been found that a cured product having a low coefficient of thermal expansion, a high peel strength, excellent heat resistance such as a high glass transition temperature, a low dielectric constant and a low dielectric loss tangent is obtained when a curing agent and a thermoplastic styrenic polymer are further contained as well.

This application is based on Japanese Patent Application No. 2020-153177 filed on Sep. 11, 2020, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition, which affords a cured product exhibiting excellent low dielectric properties, heat resistance, and adhesive properties to a metal foil and a low coefficient of thermal expansion. In addition, according to the present invention, a prepreg, a film with resin, a metal foil with resin, a metal-clad laminate, and a wiring board which are obtained using the resin composition are provided.

1. A resin composition comprising:
a polyphenylene ether compound having a carbon-carbon unsaturated double bond at a terminal;
a maleimide compound (A) having an arylene structure bonded in meta-orientation in a molecule; and
an inorganic filler.

2. The resin composition according to claim 1, wherein
the maleimide compound (A) includes a maleimide compound (A1) represented by the following Formula (1): 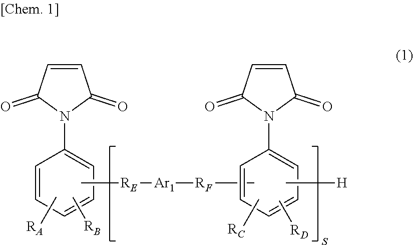
[in Formula (1), Ar₁ represents an arylene group bonded in meta-orientation, R_{A}, R_{B}, R_{C}, and R_{D} each independently represent a hydrogen atom, an alkyl group having 1 to 5 carbon atoms, or a phenyl group, R_{E} and R_{F} each independently represent an aliphatic hydrocarbon group, and s represents 1 to 5].

3. The resin composition according to claim 2, wherein
the maleimide compound (A1) represented by Formula (1) includes a maleimide compound (A2) represented by the following Formula (2): 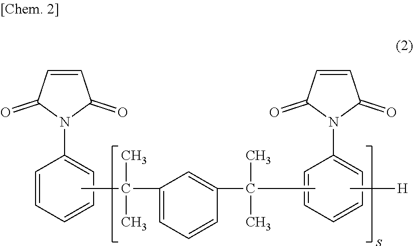
[in Formula (2), s represents 1 to 5].

4. The resin composition according to claim 1, wherein
the polyphenylene ether compound includes a polyphenylene ether compound having at least one selected from a group represented by the following Formula (3) and a group represented by the following Formula (4) at a molecular terminal: 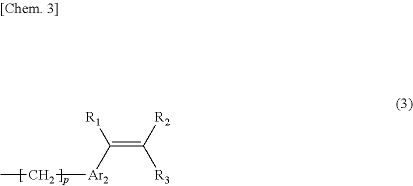
[in Formula (3), R₁ to R₃ each independently represent a hydrogen atom or an alkyl group, Ar₂ represents an arylene group, and p represents 0 to 10], 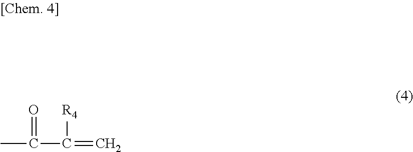
[in Formula (4), R₄ represents a hydrogen atom or an alkyl group].

5. The resin composition according to claim 1, wherein the inorganic filler includes silica.

6. The resin composition according to claim 1, wherein a content of the maleimide compound (A) is 1 to 90 parts by mass with respect to 100 parts by mass of a total mass of the polyphenylene ether compound and the maleimide compound (A).

7. The resin composition according to claim 1, further comprising a curing agent that reacts with at least one of the polyphenylene ether compound and the maleimide compound (A),
wherein the curing agent includes at least one selected from a maleimide compound (B) different from the maleimide compound (A), an epoxy compound, a methacrylate compound, an acrylate compound, a vinyl compound, a cyanate ester compound, an active ester compound, and an allyl compound.

8. The resin composition according to claim 1, further comprising a thermoplastic styrenic polymer.

9. The resin composition according to claim 1, further comprising a reaction initiator.

10. The resin composition according to claim 9, wherein the reaction initiator includes at least one selected from a peroxide and an organic azo compound.

11. A prepreg comprising:
the resin composition according to claim 1 or a semi-cured product of the resin composition; and
a fibrous base material.

12. A film with resin comprising:
a resin layer containing the resin composition according to claim 1 or a semi-cured product of the resin composition; and
a support film.

13. A metal foil with resin comprising:
a resin layer containing the resin composition according to claim 1 or a semi-cured product of the resin composition; and
a metal foil.

14. A metal-clad laminate comprising:
an insulating layer containing a cured product of the resin composition according to claim 1; and
a metal foil.

15. A wiring board comprising:
an insulating layer containing a cured product of the resin composition according to claim 1; and
wiring.

16. A metal-clad laminate comprising:
an insulating layer containing a cured product of the prepreg according to claim 11; and
a metal foil.

17. A wiring board comprising:
an insulating layer containing a cured product of the prepreg according to claim 11; and
wiring.
